(19) United States
(12) Patent Application Publication
(10) Pub. No.: US 2012/0112300 A1
(43) Pub. Date: May 10, 2012

(54) METHOD OF FORMING SILICIDE FOR CONTACT PLUGS

(76) Inventors: Huang-Shun Lin, Taipei County (TW); Yi-Tyng Wu, Chiayi City (TW); Yu-Ming Wang, Hsinchu County (TW)

(21) Appl. No.: 12/942,029

(22) Filed: Nov. 9, 2010

(51) Int. Cl. H01L 31/0232; H01L 31/18

(52) U.S. Cl. 257/432; 438/70; 257/E31.127

(57) ABSTRACT

A metal layer structure includes a substrate, a metal layer and a composite passivation. The metal layer is disposed in the substrate. The composite passivation includes a first material layer covering the substrate, an opening disposed in the first material layer and exposing the metal layer as well as a second material layer. The second material layer surrounds the sidewall of the opening, covers part of the bottom of the opening and exposes the metal layer.

### BACKGROUND OF THE INVENTION

1. Field of the Invention

The present invention generally relates to a metal layer structure and a method for forming a metal layer structure. In particular, the present invention is directed to a metal layer structure with a composite passivation surrounding the sidewall of the opening in the metal layer structure. Owing to the composite passivation surrounding the sidewall of the opening in the metal layer structure, the regions adjacent to the opening in the metal layer structure are therefore protected.

2. Description of the Prior Art

In the process for manufacturing semiconductor elements, the conductive layer which is covered by the insulating layer needs a medium to penetrate the insulating layer to construct an outward electrical connection. Generally speaking, an opening in the insulating layer is formed to expose the conductive layer by lithographic and etching procedures. By means of such opening, a medium which penetrates the insulating layer to construct an outward electrical connection can be constructed to form a conductive layer of an outward electrical connection

However, when the opening is being formed, an etchant is usually used to remove some of the insulating layer no matter which etching procedure is used. In addition, a cleaning procedure is still needed after the etching procedure to thoroughly remove the etchant or residues left in the opening because the etchant is relatively corrosive.

Although the cleaning procedure is expected to thoroughly remove the etchant or residues left in the opening, there are possibly still some corrosive chemicals left in the opening after the cleaning procedure because of the complicated chemical reactions between the etchant and the insulating layer. The inventors noticed that more or less corrosion on the conductive layer which is made of metal in the opening was still observed although a proper cleaning procedure had been carried out. Such corrosion jeopardizes the performance of the semiconductor elements and needs resolving.

### SUMMARY OF THE INVENTION

In the light of the above-mentioned problems, the present invention therefore proposes a novel metal layer structure. The novel metal layer structure of the present invention may protect the conductive layer which is made of metal in the opening from adverse corrosion, in particular the conductive layer adjacent to the corner of the insulating layer. As a result, the novel metal layer structure of the present invention is characterized in the feature of a substantially corrosion-free result.

The present invention in a first aspect proposes a novel metal layer structure. The metal layer structure of the present invention includes a substrate, a metal layer and a composite passivation. The metal layer is disposed in the substrate. The composite passivation includes a first material layer, a second material layer and an opening. The first material layer covers the substrate and the opening exposes some of the metal layer. The opening has a sidewall and a bottom exposing some of the metal layer. The second material layer surrounds the sidewall of the opening, covers part of the bottom of the opening to expose the first metal layer. At least the first material layer and the second material layer together form the composite passivation. In addition, the composite passivation may further include a third material layer so that the first material layer, the second material layer and the third material layer together form the composite passivation. The second material layer is in an L shape structure and partially disposed at the bottom of the opening. The metal layer structure of the present invention is substantially corrosion-free.

In a second aspect, the present invention proposes a method for forming a metal layer structure. First, a matrix which includes a first metal layer disposed on a substrate is provided. Second, the substrate and the first metal layer are covered by a first material layer. Later, part of the first material layer is removed to form an opening to expose the first metal layer. Next, the opening and the first material layer is covered by a second material layer. At least the first material layer and the second material layer together form a composite passivation. After that an optional semiconductor process, such as a stack color filter process, is carried out. Then the second material layer in part of the bottom of the opening is selectively removed to expose the first metal layer.

In a first embodiment of the present invention, a second material layer is first formed to cover the opening, the first material layer and the exposed first metal layer, then a third material layer is formed to cover the opening so that a first material layer, the second material layer and the third material layer together form a composite passivation. Besides, when the second material layer in the opening is selectively removed, the third material layer in the opening is also selectively removed to expose the first metal layer and the second material layer. The second material layer may be in an L shape structure and partially disposed at the bottom of the opening.

In the metal layer structure of the present invention, the composite passivation may protect the metal layer in the opening from adverse corrosion, in particular protect the conductive layer adjacent to the corner of the insulating layer. The composite passivation may also protect the metal layer in the opening from any damage or corrosion in a following or optional semiconductor process, such as a stack color filter process. As a result, the novel metal layer structure of the present invention is characterized in the feature of a substantially corrosion-free result. The composite passivation of the present invention may include at least the first material layer and the second material layer, or further include a third material layer covering the second material layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate an example of the method of the present invention.

FIG. 8 illustrates the metal layer structure of the present invention.

### DETAILED DESCRIPTION

The present invention therefore proposes a novel metal layer structure and a method for making a metal layer structure. There are at least a first material layer and a second material layer to form a composite passivation in the metal layer structure of the present invention in order to protect the conductive layer which is made of metal in the opening from adverse corrosion or damage, in particular protect the conductive layer adjacent to the corner of the insulating layer, after or during the needed process to make the metal layer structure. The novel metal layer structure of the present invention may ensure a stable electric connection.

The present invention in one aspect provides a method for forming a metal layer structure. Please refer to FIGS. 1-6, illustrating an example of the method of the present invention. First, please refer to FIG. 1, a matrix 100 is provided. The matrix 100 includes a substrate 101 and a first metal layer 102. The first metal layer 102 is disposed on the substrate 101. The substrate 101 may be a semiconductor substrate, such as Si, or a semiconductor material covered with at least one insulating layer. There may be other semiconductor elements on the substrate 101. The first metal layer 102 is for use as an input/output connecting pad, or TSV. The matrix 100 may be made by first covering the substrate 101 with the first metal layer 102, then the first metal layer 102 being optionally removed so that the first metal layer 102 is disposed on the substrate 101. Alternatively, trenches (not shown) are first formed in the insulating layer (not shown) on the substrate 101, and then the metal material is planarized after the metal material fills the trenches.

Optionally, there may be a second metal layer 103 on the first metal layer 102 to cover part of the first metal layer 102 to form a composite connecting pad. The first metal layer 102 may be any conductive material for use in the semiconductor process, such as Al, Cu and the second metal layer 103 may be any anti-reflective material for use in the semiconductor process, such as Ti, TiN. FIG. 1 illustrates there are a second metal layer 103 and a first metal layer 102 simultaneously on the substrate 101.

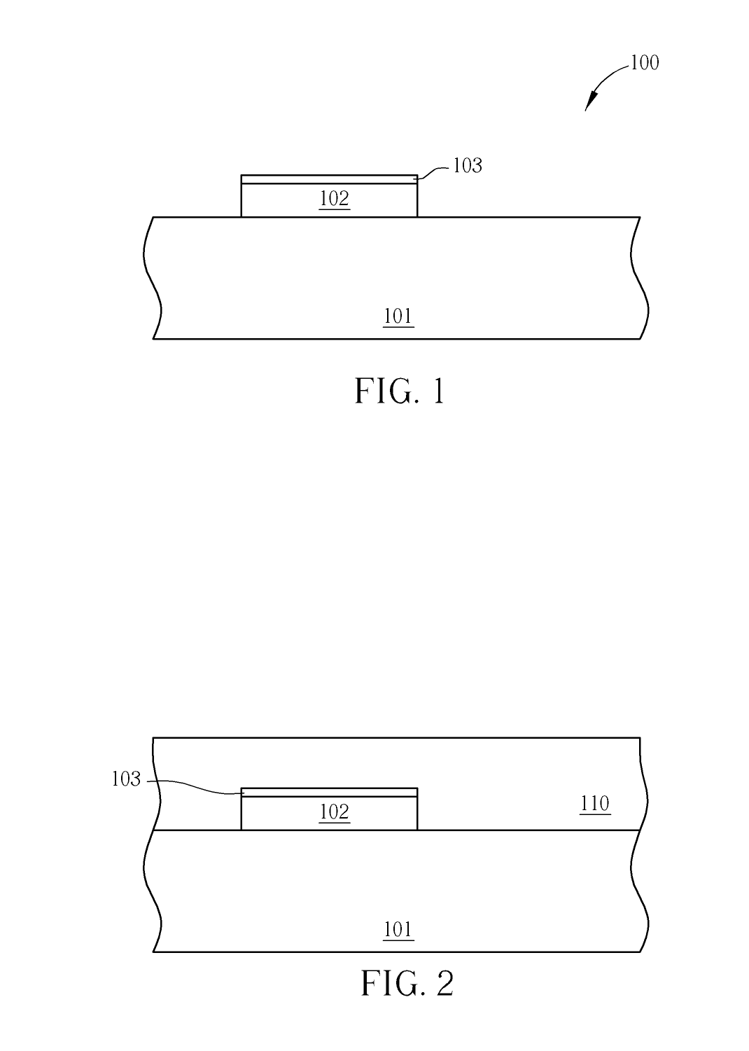

Second, please refer to FIG. 2, a first material layer 110 is formed to directly cover the substrate 101 and the metal layer(s). If there is only one metal layer, i.e. the first metal layer 102, the first material layer 110 directly covers the first metal layer 102 and the substrate 101. If both the first metal layer 102 and the second metal layer 103 are present, the first material layer 110 directly covers the first metal layer 102, the second metal layer 103 and the substrate 101. Optionally, the first material layer 110 may be a composite material layer or not. The first material layer 110 may include an insulating material such as oxide, oxynitride or nitride, like silicon oxide.

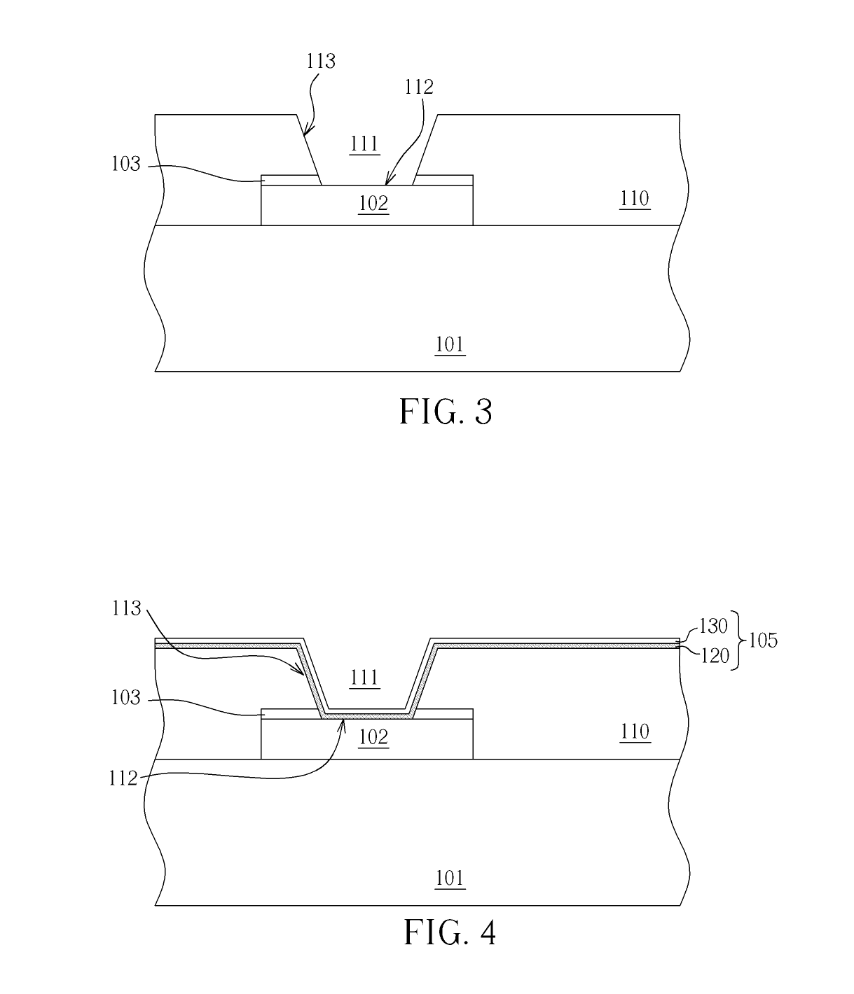

Later, please refer to FIG. 3, part of the first metal layer 110 is removed to form an opening 111. A suitable etching procedure, such as dry etching procedure, along with a patterned mask (not shown) made from lithography may be used to form the opening 111. If there is only one metal layer, i.e. the first metal layer 102, the opening 111 in the first metal layer 110 is supposed to expose the first metal layer 102. If both the first metal layer 102 and the second metal layer 103 are present, the opening 111 still directly exposes the first metal layer 102 because the etching procedure removes some of the second metal layer 103 as well. Accordingly, the etching procedure may be a multi-step etching procedure. The opening 111 has a bottom 112 and a sidewall 113. The bottom 112 exposes the first metal layer 102 and the sidewall 113 exposes the first material layer 110.

Next, please refer to FIG. 4, a second material layer 120 and an optional third material layer 130 respectively cover the opening 111 and the first material layer 110. For example, the second material layer 120 is first deposited then the optional third material layer 130 is later deposited. If there is only the second material layer 120, the first material layer 110 and the second material layer 120 together form a composite passivation 105, to protect the semiconductor elements on the substrate 101. If the second material layer 120 and the third material layer 130 are both present, the first material layer 110, the second material layer 120 and the third material layer 130 together form the composite passivation 105. The second material layer 120 may be an insulating material such as oxide, oxynitride or nitride like tetraethoxysilane (TEOS) and has a thickness of 200 Å to 500 Å. The third material layer 130 may be an insulating material such as oxide, oxynitride or nitride like silicon nitride and has a thickness of 200 Å to 500 Å. Nevertheless, the second material layer 120 and the third material layer 130 are always not the same.

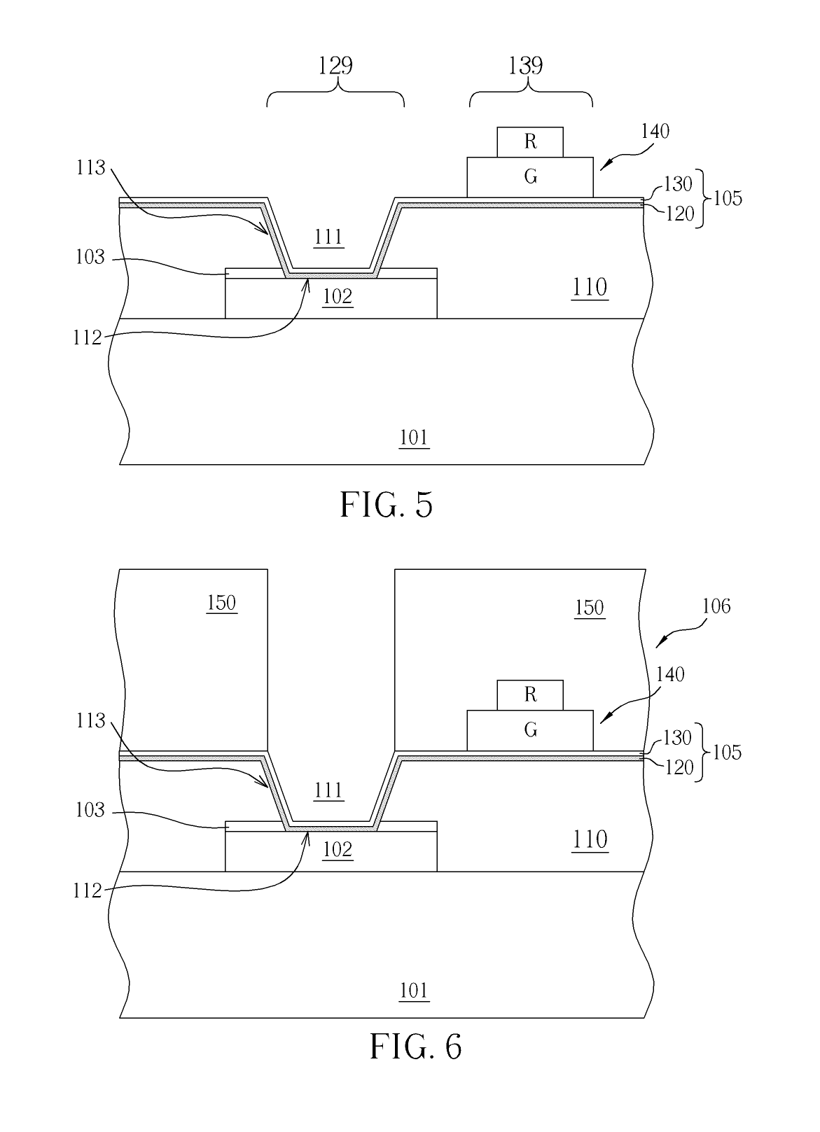

After that, please refer to FIG. 5, at least an optional semiconductor process is carried out. For example, for an integrated contact image sensor (CIS) process, there are corresponding sensors (not shown) or control elements (not shown) on the substrate 101 so a procedure to form a set of stack color filters follows. The color filters 140 are formed on the first material layer 110 in the sensor region 139 and stay away from the opening 111 in the periphery region 129. If there is only the second material layer 120, the color filters 140 are in direct contact with the second material layer 120. If both the second material layer 120 and the third material layer 130 are present, the color filters 140 are in direct contact with the third material layer 130. FIG. 5 illustrates an example of both the second material layer 120 and the third material layer 130 present, so the color filters 140 are in direct contact with the third material layer 130.

Other semiconductor processes are possible, such as passive elements, MEMS. Under the protection of the composite passivation 105 of the present invention, the first metal layer 102 in the opening 111 is free from the damage or corrosion after or during the optional semiconductor processes.

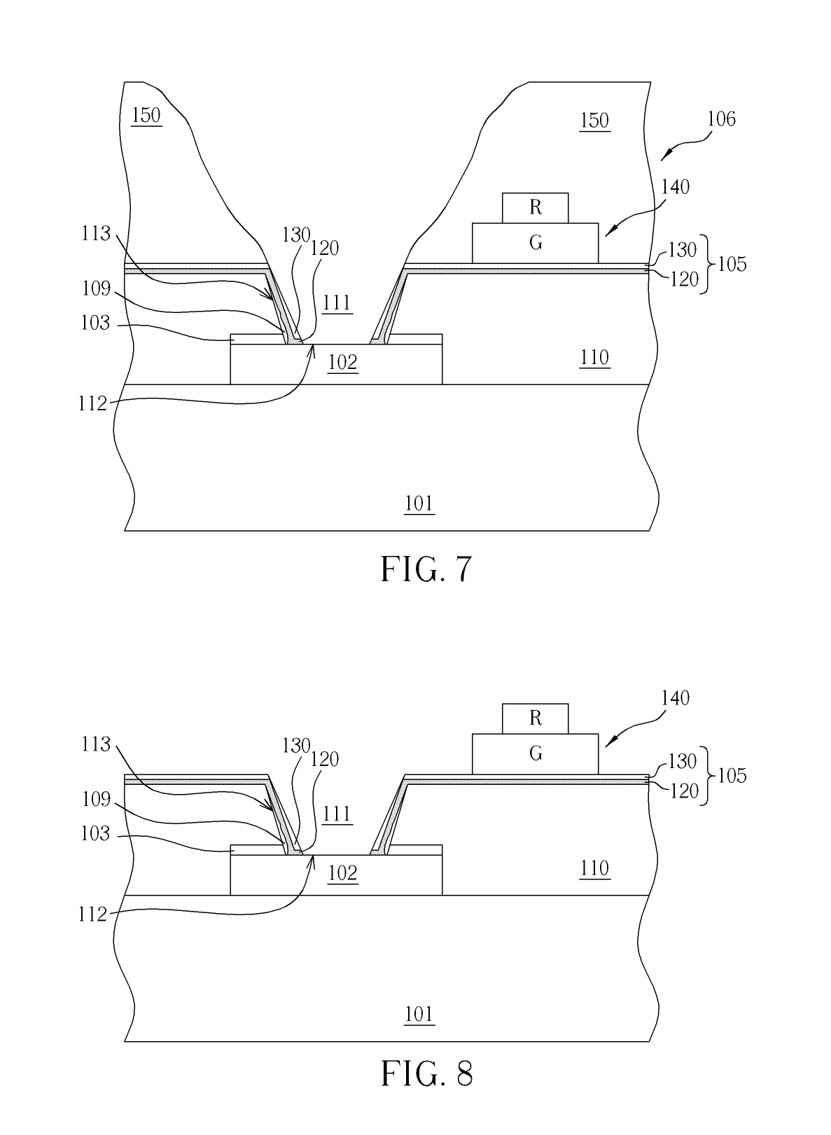

Afterwards, please refer to FIGS. 6 and 7. The second material layer 120 in part of the bottom of the opening 111 is selectively removed to expose the first metal layer 102. A suitable etching method, such as dry etching procedure, along with a patterned mask, such as a photoresist 150, made from lithography may be used to expose the first metal layer 102. Because a corrosive chemical, such as a development agent, is used to develop the photoresist 150, the composite passivation 105 in the metal layer structure 106 of the present invention protects the first metal layer 102 in the opening 111. If both the second material layer 120 and the third material layer 130 are present, the etching procedure removes some of the second material layer 120 and some of the third material layer 130 in the opening 111 to expose the first metal layer 102. The photoresist 150 is removed in the end.

Due to the block of the third material layer 130, the etching procedure should remove most of the third material layer 130. However, there is still some third material layer 130 left on the sidewall 113. The second material layer 120 now becomes an L structure and some of it is disposed at the bottom 112 of the opening 111 near the first metal layer 102. The second material layer 120 covers part of the bottom 112 of the opening 111 and exposes the first metal layer, so in particular to protect the first metal layer 102 near the corner of the opening 111, which effectively keeps the corrosive chemical from penetrating it and avoids corrosion. If there is any etching residue 109 left in the opening 111 coming from the previous steps, such as the etching procedure, the composite passivation 105 of the present invention keeps the etching residues 109 from being exposed. As a result, the first metal layer 102 is free of corrosion after it is exposed.

After the previous steps, the present invention in a second aspect also provides a metal layer structure. Please refer to FIG. 8, illustrating the metal layer structure of the present invention. The metal layer structure 106 of the present invention includes a substrate 101, a metal layer and a composite passivation 105. The metal layer is disposed on the substrate 101. The metal layer includes a first metal layer 102 and an optional second metal layer 103 to cover the outer surface of the first metal layer 102. The first metal layer 102 may be any conductive material for use in the semiconductor process, such as Al, Cu and the second metal layer 103 may be any anti-reflective material for use in the semiconductor process, such as Ti, TiN.

The composite passivation 105 includes at least a first material layer 110, a second material layer 120 and an opening 111. The opening 111 is in the first material layer 110 which covers the substrate 101. No matter if the second metal layer 103 is present or not, the opening 111 always directly exposes the first metal layer 102. In addition, the opening 111 has a bottom 112 and a sidewall 113. The bottom 112 exposes the first metal layer 102.

The second material layer 120 surrounds the sidewall 113 of the opening 110 and covers part of the bottom 112 of the opening 111 so it exposes the first metal layer 102 as well. In addition, the composite passivation 105 may further include a third material layer 130. The third material layer 130 is in direct contact with the second material layer 120 without directly contacting the first material layer 110. The second material layer 120 may have an L-shape structure.

The first material layer 110 may includes an insulating material such as oxide, oxynitride or nitride, like silicon oxide. The second material layer 120 may be an insulating material such as oxide, oxynitride or nitride such as tetraethoxysilane (TEOS) and has a thickness of 200 Å to 500 Å. The third material layer 130 may be an insulating material such as oxide, oxynitride or nitride like silicon nitride and has a thickness of 200 Å to 500 Å. Nevertheless, the second material layer 120 and the third material layer 130 are always not the same.

Optionally, the metal layer structure 106 of the present invention may further include color filters 140, such as a set of stack color filters, formed on the first material layer 110 and in direct contact with the second material layer 120 or indirect contact with the third material layer 130. Under the protection of the composite passivation 105 of the present invention, the first metal layer 102 in the first material layer 110 near the corner of the opening 111 is particularly protected. If there is any etching residue 109 left in the opening 111 coming from some processing steps, such as an etching procedure, the composite passivation 105 of the present invention keeps etching residues 109 from being exposed. As a result, the first metal layer 102 is free of corrosion after the first metal layer 102 is exposed.

Those skilled in the art will readily observe that numerous modifications and alterations of the device and method may be made while retaining the teachings of the invention.

1. A metal layer structure, comprising:
a substrate;
a first metal layer disposed on said substrate; and
a composite passivation comprising a first material layer covering said substrate, an opening disposed in said first material layer and exposing said first metal layer as well as a second material layer which surrounds the sidewall of said opening, covers part of the bottom of said opening and exposes said first metal layer.

2. The metal layer structure of claim 1, wherein said second material layer covers the outer surface of said first material layer.

3. The metal layer structure of claim 1, further comprising:
a second metal layer covering part of said first metal layer and exposes said first metal layer through said opening.

4. The metal layer structure of claim 1, further comprising:
a third material layer covering the sidewall of said opening and in direct contact with said second material layer.

5. The metal layer structure of claim 4, wherein said second material layer is in an L shape structure and partially disposed at the bottom of said opening.

6. The metal layer structure of claim 4, wherein said first material layer, said second material layer and third material layer are independently selected from a group consisting of silicon oxide, silicon oxynitride, and silicon nitride.

7. The metal layer structure of claim 4, wherein said second material layer and third material layer independently have a thickness of 200 Å to 500 Å.

8. The metal layer structure of claim 1, wherein said second material layer comprises tetraethoxysilane (TEOS).

9. The metal layer structure of claim 1, wherein said first metal layer is substantially free of corrosion.

10. The metal layer structure of claim 1, further comprising:
a color filter disposed on said first material layer and away from said opening.

11. A method for forming a metal layer structure, comprising:
providing a matrix comprising a first metal layer disposed on a substrate;
covering said substrate and said first metal layer with a first material layer;
removing part of said first metal layer to form an opening to expose said first metal layer;
covering said opening and said first material layer with a second material layer, wherein at least said first material layer and said second material layer together form a composite passivation;
performing a semiconductor process;
selectively removing said second material layer in part of the bottom of said opening to expose said first metal layer.

12. The method for forming a metal layer structure of claim 11, wherein said semiconductor process comprises forming a color filter disposed on said second material layer.

13. The method for forming a metal layer structure of claim 11, further comprising:
forming a second metal layer covering part of said first metal layer; and
removing part of said first material layer and said second metal layer to form said opening to expose said first metal layer.

14. The method for forming a metal layer structure of claim 11, after covering said opening and said first material layer with said second material layer further comprising:
covering said opening, said second material layer and said first metal layer with a third material layer, wherein said first material layer, said second material layer and said third material layer together form said passivation.

15. The method for forming a metal layer structure of claim 14, wherein selectively removing said second material layer in said opening also selectively removes said third material layer in said opening to expose said first metal layer and part of said second material layer.

16. The method for forming a metal layer structure of claim 11, wherein said second material layer is in an L shape structure and partially disposed at the bottom of said opening.

17. The method for forming a metal layer structure of claim 14, wherein said first material layer, said second material layer and third material layer are independently selected from a group consisting of silicon oxide, silicon oxynitride, and silicon nitride.

18. The method for forming a metal layer structure of claim 14, wherein said second material layer and third material layer independently have a thickness of 200 Å to 500 Å.

19. The method for forming a metal layer structure of claim 11, wherein said second material layer comprises tetraethoxysilane (TEOS).

20. The method for forming a metal layer structure of claim 11, wherein said first metal layer is substantially free of corrosion after selectively removing said second material layer in said opening to expose said first metal layer.
